(19) United States
(12) Patent Application Publication
(10) Pub. No.: US 2013/0280660 A1
(43) Pub. Date: Oct. 24, 2013

(54) METHOD OF PATTERING NONMETAL CONDUCTIVE LAYER

(71) Applicants: Chien-Cheng CHANG, Taoyuan County (TW); Yu-Chun CHIEN, Taoyuan County (TW); Da-Shan LIN, Taoyuan County (TW); Han-Hsiang LIN, Taoyuan County (TW)

(72) Inventors: Chien-Cheng CHANG, Taoyuan County (TW); Yu-Chun CHIEN, Taoyuan County (TW); Da-Shan LIN, Taoyuan County (TW); Han-Hsiang LIN, Taoyuan County (TW)

(73) Assignee: FAR EASTERN NEW CENTURY CORPORATION, Taipei (TW)

(21) Appl. No.: 13/592,330

(22) Filed: Aug. 22, 2012

(30) Foreign Application Priority Data
Apr. 20, 2012 (TW) 101114215

(51) Int. Cl. G03F 7/20; B82Y 30/00

(52) U.S. Cl. 430/313; 977/742; 977/734; 977/750; 977/752

(57) ABSTRACT

A method of patterning a nonmetal conductive layer on a circuit board is provided. A nonmetal conductive layer and a negative photoresist layer are sequentially formed on a substrate of a circuit board. Then, the negative photoresist layer is exposed through a patterned photomask and then developed by a developing solution. Next, the nonmetal conductive layer is etched. The remained photoresist layer is finally removed by a non-alkaline stripper solution to obtain a patterned nonmetal layer on the substrate.

### CROSS-REFERENCE TO RELATED APPLICATION

This application claims the priority benefit of Taiwan application serial no. 101114215, filed Apr. 20, 2012, the full disclosure of which is incorporated herein by reference.

### BACKGROUND

1. Technical Field

The disclosure relates to a method of patterning a conductive layer. More particularly, the disclosure relates to a method of patterning a nonmetal conductive layer.

2. Description of Related Art

With the advance of science and technology, an electronic product needs more functions, and becomes slimmer and lighter. Therefore, the integration density of integrated circuits becomes higher, and the line width of conductive lines in the integrated circuits becomes narrower. Commonly used processes for fabricating the conductive lines include photolithography and etching processes. Especially in semiconductor manufacturing, various patterned thin films, including thin films in MOS (metal-oxide-semiconductor), are all manufactured by processes including photolithography and etching processes.

The photolithography technology is originated from photoengraving, and extensively used in semiconductor processes. The photolithography is used to transfer patterns on a photomask to a photoresist from 1970. Photoresist is a light-sensitive material. After irradiating light on photoresist through a patterned photomask, the irradiated portions of the photoresist can undergo some photoreaction to build or break some chemical bonds. Therefore, some portions of the photoresist can dissolve in a developing solution, and some portions cannot. Since the photoresist can be classified to positive and negative photoresist, the patterns of the developed photoresist can be the same as or complementary to the patterns on the photomask. For positive photoresist, the irradiated portions become soluble in the developing solution to leave a same pattern as the photomask. For negative photoresist, the irradiated portions become insoluble in the developing solution to leave a complementary pattern of the photomask.

Since the transmittance of metal layer is not enough, transparent metal oxide conductor, such as indium tin oxide (ITO), is used as a conductive layer. ITO can also be patterned by photolithography and etching processes. The photoresist used to pattern ITO is positive photoresist, and a strong acid is used to etch the ITO. Finally, the residue photoresist is stripped by a strong alkaline stripper.

ITO needs rare metal. Therefore, some suggests using carbon nanotube (CNT) to replace ITO as a transparent conductive layer. However, the conductivity of CNT can be decreased by strongalkali, and even completely lose the conductivity. Therefore, the conditions of pattering the ITO layer cannot be used to pattern the CNT layer. Suitable photolithography and etching processes are needed for the CNT layer.

### SUMMARY

In one aspect, the present invention is directed to a method of fabricating a circuit board having a patterned conductive layer. The method comprises the following steps.

A conductive laminated layer, including a substrate and a nonmetal conductive layer thereon, is provided first. Then, a negative photoresist layer is formed on the nonmetal conductive layer. The negative photoresist layer is exposed through a patterned photomask by a radiation light to crosslink the exposed negative photoresist. The non-exposed part of the negative photoresist is removed by a developing solution to leave the exposed part of the negative photoresist layer. The nonmetal conductive layer is then etched by an etching solution to remove the nonmetal conductive layer unshielded by the patterned negative photoresist, whereby a patterned nonmetal conductive layer of a circuit board is obtained. The remained photoresist layer is finally removed by a non-alkaline stripper solution to obtain a patterned nonmetal layer on the substrate.

Accordingly, the method provided above can effectively patterning the nonmetal conductive layer without damaging the conductivity of the nonmetal conductive layer.

### BRIEF DESCRIPTION OF THE DRAWINGS

FIGS. 1A-1E are cross-sectional diagrams of a method for fabricating a circuit board having a patterned conductive layer according to an embodiment of this invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

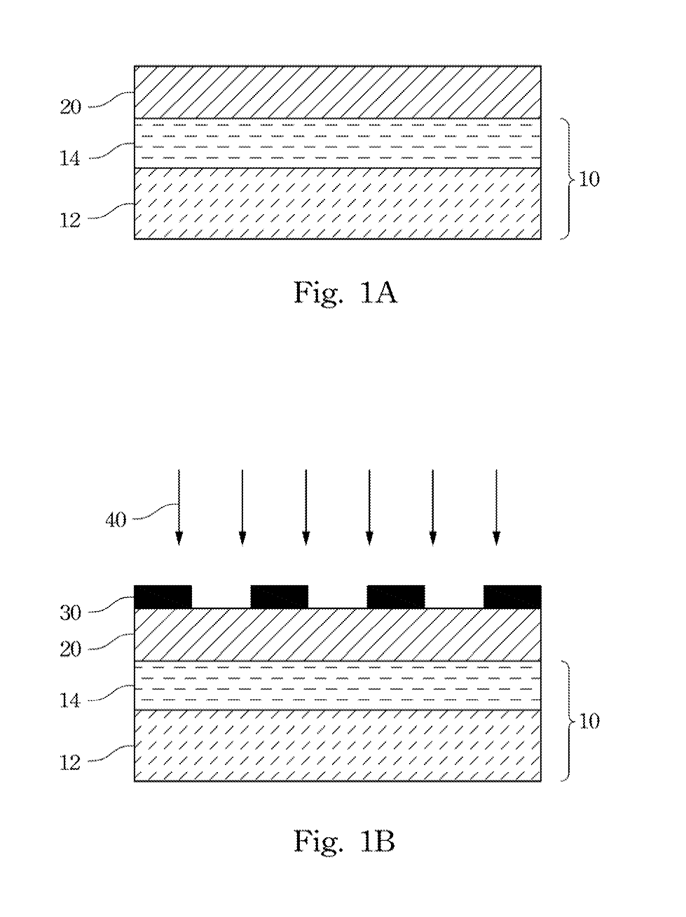

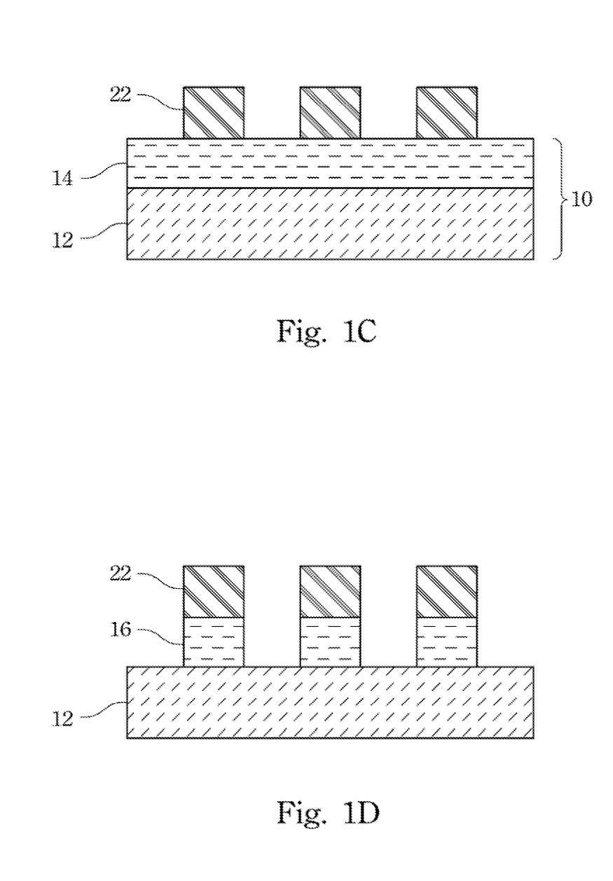

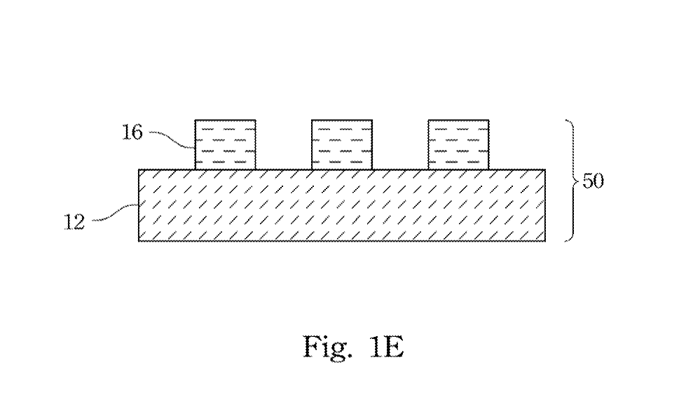

FIGS. 1A-1E are cross-sectional diagrams of a method for fabricating a circuit board having a patterned conductive layer according to an embodiment of this invention. In FIG. 1, a conductive laminated layer 10 is provided. The laminated layer 10 comprises a substrate 12 and a conductive layer 14.

The material of the substrate 12 has no particular limitations thereto; any suitable materials can be used for the substrate 12. The examples of the suitable materials for the substrate 12 can be a polyester-based resin, such as polyethylene terephthalate (PET), or polyethylene naphthalate (PEN); a polyolefin-based resin, such as polypropylene (PP), cyclo-olefin polymer (COP), high-density polyethylene (HDPE), or low-density polyethylene (LDPE); a polyvinyl-based resin, such as polyvinyl chloride (PVC), or polyvinylidene chloride; a cellulose ester, such as triacetate cellulose (TAC), acetate cellulose; a polycarbonate-based resin, such as polycarbonate (PC); a polyvinyl acetate) or an derivative thereof, such as polyvinyl alcohol); an acrylic resin, such as polymethacrylate, a copolymer of polymethacrylate, or poly(methyl methacrylate) (PMMA); polyamides; polyimides; a polyacetal resin; a phenolic resin; an aminoplastics, such as an urea-formaldehyde resin, or melamine-formaldehyde resin; an epoxide resin; a urethane; a polyisocyanurate; a furan resin; a silicone; a casesin resin; a cyclic thermoplastic, such as a cyclic olefin polymer, or a styrenic polymer; a fluorine-containing polymer; a to polyethersulfone; or glass. PET is preferred in the materials mentioned above.

The thickness of the substrate 12 does not have particular limitations, and can be chosen according various requirements. The thickness of the substrate 12 is preferably 2-300 μm, and more preferably 10-250 μm. Generally speaking, the mechanical strength will be insufficient when the thickness of the substrate 12 is less than 2 μm, and it will not facilitate the formation of the conductive layer 14. On the contrary, the total transmittance of the conductive laminated layer 10 will be decreased when the thickness of the substrate 12 is more than 300 μm, and it will not facilitate the thinning requirement of the electronic devices.

The thickness of the conductive layer 14 has no particular limitations, and can be chosen according to various requirements. The thickness of the conductive layer 14 is preferably 10-200 nm, and more preferably 20-150 nm. Generally speaking, the conductivity can be nonuniform, or the resistance can be too high when the thickness of the conductive layer 14 is less than 10 nm. Contrarily, in addition to the high cost, the total transmittance of the laminated conductive layer 10 will be decreased when the thickness of the conductive layer 14 is more than 200 μm, and it will not facilitate the thinning requirement of the electronic devices.

The material of the conductive layer 14 is preferably a nonmetal conductive material. However, any persons skilled in the art will appreciate that the method provided by this disclosure can be modified to adopt metal conductive material, such as gold, silver, copper . . . etc., or metal oxide conductive material, such as indium oxide, tin oxide, indium tin oxide . . . etc. The nonmetal conductive material above is the conductive material that is not the metal or the metal oxide above. The nonmetal conductive material is preferably a conductive polymer, a carbon nanomaterial, or a combination thereof. The conductive polymer can be, but is not limited to, polypyrrole, polyaniline, polythiophene, or any combinations thereof. More specifically, the conductive polymer includes poly(3,4-ethylenedioxythiophene)-poly(styrenesulfonate) (PEDOT-PSS), but is not limited thereto. The carbon nanomaterial has no particular limitations, any carbon nanomaterials satisfying the requirements of conductivity, transparency, or any other properties can be used. For example, the carbon nanomaterials can be carbon nanotubes, carbon nanofibers, fullerenes, graphene, or nano graphite, and is not limited thereto. The carbon nanotubes can be single-walled carbon nanotubes, double-walled carbon nanotubes, multi-walled carbon nanotubes, or any combinations thereof, but is not limited thereto.

When the carbon nanotubes are used to be the material of the conductive layer 14, a binder is needed to assist coating the carbon nanotubes on the substrate 12. The binder has no particular limitations, and a person skilled in the art can choose any suitable binder for the carbon nanotubes to fit the needs. The binder is preferably polyurethane, for example. In addition, the diameter and the length of the carbon nanotubes also do not have particular limitations. Any person skilled in the art can chose suitable diameter and length of the carbon nanotubes. Generally speaking, the diameter of the carbon nanotubes is preferably 1-50 nm, more preferably 1-30 nm, and even more preferably 3.25 nm. The length of the carbon nanotubes is preferably to be 1-20 μm, more preferably 5-20 μm, and even more preferably 10-20 μm.

The manner of disposing the conductive layer 14 on the substrate 12 can be any manners that can well adhere the conductive layer 14 to the substrate 12. Therefore, there are no particular limitations to the disposing manner of the conductive layer 14 on the substrate 12. For example, the conductive layer 14 can be disposed on the substrate 12 by coating. More particularly, the coating method above can be wet coating, but is not limited thereto.

After obtaining the conductive laminated layer 10, a photoresist layer 20 is coated on the conductive layer 14. The photoresist layer 20 is made from a negative photoresist, which comprises, but is not limited by, cyclized polyisoprene, an alkali-soluble acrylic resin, a copolymer containing hydroxystyrene monomer, or any combinations thereof. The cyclized polyisoprene is preferably used. The thickness of the photoresist layer 20 has no particular limitations. Considering the operation convenience and the cost, the thickness of the photoresist layer 20 is preferably 0.1-50 μm, more preferably 0.5-30 μm, and even more preferably 1-5 μm. The coating method of the photoresist layer 20 has no particular limitations. According to the requirements of the coating method, such as solid content or viscosity of the photoresist coating solution, or operation suggestion from the photoresist's vender, one can choose a suitable operational method to coat the photoresist layer 20. For example, the coating method of the photoresist layer 20 can be spin coating, roller coating, immersing, casting, spraying, injecting, screen printing, or thin layer coating, but is not limited thereto.

In FIG. 18, a photomask 30 having a pattern is further disposed on the photoresist layer 20 for transferring the pattern to the photoresist layer 20. The material of the photomask 30 has no particular limitations. The only requirement for the material of the photomask 30 is being able to effectively shield radiation light 40. For example, the photomask 30 can be a glass photomask having transparent areas and opaque areas, or flexo-mask, but is not limited thereby. The photomask 30 can be formed by directly coating on the photoresist layer 20, or being made into a plate or a film and then being removably attached on the surface of the photoresist layer 20. When necessary, a glue layer can be further disposed between the photomask 30 and the photoresist layer 20 to avoid the movement of the photomask 30 and thus the influence of the exposure precision. The formation of the glue layer can be coating a pressure sensitive adhesive on the plate or the film of the photomask 30, for example, but is not limited thereby.

After disposing the photomask 30 on the photoresist layer 20, radiation light 40 is applied over the photomask 30 to crosslink the unshielded portions of the photoresist layer 20. The wavelength of the radiation light 40 has no particular limitations, and a suitable wavelength can be chosen to fit the photoresist layer 20. The radiation light 40 can be ultraviolet light, visible light, electron beam, or X-ray, but is not limited thereby. The radiating time and dose can be chosen to fit the kinds and thickness of the photoresist layer, and does not have particular limitations. The radiating dose is preferably 100 mJ/cm² at most, and more preferably 40-80 mJ/cm².

In FIG. 1C, after removing the photomask 30, the photoresist 22 is developed by a developing solution to remove the shielded portions of the photoresist 22. These shielded portions of the photoresist 22 are not cross-linked since not irradiated by light radiation. Therefore, these shielded portions of the photoresist 22 can dissolve in the developing solution and thus be removed. Consequently, only the exposed photoresist 22 can be left on the conductive layer 14. The developing solution above is better to be xylene, phenylethane, toluene, or a combination thereof.

The exposed photoresist 22 can be further baked after the developing step to remove the solvent contained in the exposed photoresist 22. Therefore, a deformation problem resulted from swelling the exposed photoresist 22 by adsorbing solvent can be avoided, and the etching precision can be thus elevated.

In FIG. 1D, the conductive layer 14 is then etched by an etching solution. The unshielded portions of the conductive layer 14 will lose its conductivity or dissolve in the etching solution and thus be removed. The shielded portions of the conductive layer 14 are left to form a patterned conductive layer 16. The etching solution above is better to be sodium hypochlorite, hydrogen peroxide, potassium permanganate, potassium dichromate, sodium hydroxide, potassium hydroxide, or any combinations thereof.

In FIG. 1E, the photoresist 22 (not shown) is removed by a photoresist stripper to obtain the circuit board 50 having the patterned conductive layer 16. The applicable photoresist stripper can be a non-alkaline stripper or a solvent stripper. The pH value of the non-alkaline stripper is better to be less than 7. For example, the main component of the non-alkaline stripper can be sulfuric acid. The main component of the solvent stripper is preferably to be a mixture solution of alkylbenzene sulfonic acid and heavy aromatic solvent naphtha, or dodecyl benzenesulfonic acid.

In light of foregoing, the photolithography and etching conditions provided above can be used to effectively etch a nonmetal conductive layer and does not affect the conductivity of the circuit made from the patterned nonmetal conductive layer after the etching. Therefore, a circuit board with a patterned nonmetal conductive layer is obtained.

### Embodiment 1

A PET film (300 mm×250 mm, thick 188 μm, model A4300 from TOYOBO) was coated by a carbon nanotube (CNT) conductive solution (or called as CNT ink) by a wire bar (purchased from RIDS), and then baked in an oven (model RHD-452 from Prema) at a temperature of 120° C. for 2 minutes to remove the solvent in the CNT conductive solution. An about 100 nm thick of CNT conductive layer is thus formed on the PET film.

A negative photoresist HR-200 (the main component is cyclized polyisoprene, from Fujifilm, Japan) is spin coated on the CNT conductive layer by a spin coater (model WS-400A-6NPP from Laurell Technologies) to form a photoresist layer on the CNT conductive layer. Then, the photoresist layer is heated by a heater plate (model HP-303D from NEWLAB) at a temperature of 80±5° C. for 2 minutes to remove the solvent in the photoresist layer. Thus, a photoresist layer of about 1 μm thickness is obtained.

A photomask made from a glass plate (purchased from M&R Nano Technology) was taken to cover the photoresist layer. The line widths and the intervals between lines of the glass photomask were both 100 μm. A UV exposing machine (model 1300 MB from Fusion UV) was used to irradiating the photoresist layer through the glass photomask. The exposing dose of the photoresist layer was 80 mJ/cm².

After removing the glass photomask, the photoresist layer was developed by xylene to remove unexposed portions of the photoresist layer. The residue xylene was washed away by water for several times. Then, the semi-finished circuit board was baked in an oven at a temperature of 135±5° C. for 2 minutes to form a dried and patterned photoresist layer.

The exposed CNT conductive layer was then etched by 12 wt % of sodium hypochlorite for 1 minute, and then washed by water and then dried to obtain the needed patterned CNT conductive layer.

Finally, a photoresist stripper of alkylbenzene sulfonic acid and heavy aromatic solvent naphtha (model EKC-922 from DuPont) was heated to 80±5° C. to immerse the patterned photoresist layer on the patterned CNT conductive layer for 2 minutes. The patterned photoresist layer was completely stripped off from the patterned CNT conductive layer, and then washed by water and dried to obtain the circuit board with patterned CNT conductive layer thereon.

The above-obtained circuit board was tested by the following tests, and the test results are listed Table 1.

[Photoresist Stripping Test]

The above-obtained circuit board was inspected by eyes through 40× optical microscope to observe whether the surface of the patterned CNT conductive layer has residue photoresist on it or not. If smaller than 1 of the surface of the CNT conductive layer was covered by the residue photoresist, a symbol of “◯” was used. If 1-5% of the surface of the CNT conductive layer was covered by the residue photoresist, a symbol of “Δ” was used. If 1more than 5% of the surface of the CNT conductive layer was covered by the residue photoresist, a symbol of “X” was used.

[Etching Precision]

The above-obtained circuit board was inspected by eyes through 40× optical microscope to observe the line widths and intervals between lines of the patterned CNT conductive layer. If the line widths were more than 90 μm, a symbol of “◯” was used. If the line widths were 50-90 μm, a symbol of “Δ” was used. If the line widths were less than 50 μm, a symbol of “◯” was used.

[Surface Resistance]

The above-obtained circuit board was first cut into a size of 5 cm×5 cm, and then measured by a surface resistance meter (LORESTA GP MODEL of MCP-T600, from Mitsubishi, Japan) to test the conductivity of the patterned CNT conductive layer. If the ratio of the after-treated surface resistance (R) over the initial surface resistance (Ro) was smaller than 1.1, a symbol of “◯” was used. If the ratio of the after-treated surface resistance (R) over the initial surface resistance (Ro) was 1.1-1.2, a symbol of “Δ” was used. If the ratio of the after-treated surface resistance (R) over the initial surface resistance (Ro) was more than 1.2, a symbol of “X” was used.

[Insulation]

The above-obtained circuit board was first cut into a size of 5 cm×5 cm, and then measured by a multimeter (model DM-2630 from HOLA) to obtain the to resistance of the etched areas (intervals between conductive lines). The resistance of the etched areas can be used to evaluate the etching results. If the measured resistance was more than 100 M·ohm, a symbol of “∘” was used. If the measured resistance was 25-100 M·ohm, a symbol of “Δ” was used. If the measured resistance was smaller than 25 M·ohm, a symbol of “X” was used.

### Embodiment 2

The preparation conditions of the Embodiment 2 were the same as the preparation conditions of the Embodiment 1 The only difference was the developing solution that was changed to phenylethane. Then, the same tests were performed on the circuit board of the Embodiment 2. The obtained results are listed in Table 1.

### Embodiment 3

The preparation conditions of the Embodiment 3 were the same as the preparation conditions of the Embodiment 1, but the developing solution was changed to toluene. Then, the same tests were performed on the circuit board of the Embodiment 3. The obtained results are listed in Table 1.

### Embodiment 4

The preparation conditions of the Embodiment 4 were the same as the preparation conditions of the Embodiment 1 but the etching solution was changed to 35 wt % of H₂O₂. Then, the same tests were performed on the circuit board of the Embodiment 4. The obtained results are listed in Table 1.

### Embodiment 5

The preparation conditions of the Embodiment 5 were the same as the preparation conditions of the Embodiment 1, but the etching solution was changed to 5 wt % of KMnO₄. Then, the same tests were performed on the circuit board of the Embodiment 5. The obtained results are listed in Table 1.

### Embodiment 6

The preparation conditions of the Embodiment 6 were the same as the preparation conditions of the Embodiment 1 but the etching solution was changed to 2.5 wt % of NaOH. Then, the same tests were performed on the circuit board of the Embodiment 6. The obtained results are listed in Table 1.

### Embodiment 7

The preparation conditions of the Embodiment 7 were the same as the preparation conditions of the Embodiment 1, but the etching solution was changed to 2.5 wt % of KOH. Then, the same tests were performed on the circuit board of the Embodiment 7. The obtained results are listed in Table 1.

### Embodiment 8

The preparation conditions of the Embodiment 8 were the same as the preparation conditions of the Embodiment 1 but the photoresist stripper was changed to 97 wt % of H₂SO₄. Then, the same tests were performed on the circuit board of the Embodiment 8. The obtained results are listed in Table 1.

### Embodiment 9

The preparation conditions of the Embodiment 9 were the same as the preparation conditions of the Embodiment 1, but the photoresist stripper was changed to dodecylbenzene sulfonic acid (Model Microstrip from Fujifilm). Then, the same tests were performed on the circuit board of the Embodiment 9. The obtained results are listed in Table 1.

### Embodiment 10

The preparation conditions of the Embodiment 10 were the same as the preparation conditions of the Embodiment 1, but the photoresist was changed to a negative photoresist SC-100 (the main component is cyclized polyisoprene, from Fujifilm, Japan). Then, the same tests were performed on the circuit board of the Embodiment 10. The obtained results are listed in Table 1.

### Comparative Example 1

The preparation conditions of the Comparative Embodiment 1 were the same as the preparation conditions of the Embodiment 1. But, the photoresist changed to a positive photoresist TFP600 (the main component is novolak resin, from AZ Electronic Materials, Taiwan); the developing solution was changed to alkaline organic developing solution (model AZ 300 MIF, 2.38 wt % TMAH, standard recipe, from AZ Electronic Materials, Taiwan); and the photoresist stripper was changed to N-methylpyrrolidinone (model AZ 400T, from AZ Electronic Materials, Taiwan). Then, the same tests were performed on the circuit board of the Comparative Embodiment 1. The obtained results are listed in Table 1.

### Comparative Example 2

The preparation conditions of the Comparative Embodiment 2 were the same as the preparation conditions of the Embodiment 1. But, the photoresist was changed to a positive photoresist AZ 6112 (the main component is naphthoquinone diazide derivative and novolak resin, from AZ Electronic Materials, Taiwan); the developing solution was changed to 2.5 wt % of KOH aqueous solution; and the photoresist stripper was changed to N-methyl pyrrolidinone (model AZ 300T, from AZ Electronic Materials, Taiwan). Then, the same tests were performed on the circuit board of the Comparative Embodiment 2. The obtained results are listed in Table 1.

TABLE 1
Tested results of the Embodiments and the Comparative Embodiments

| | | Developing | Etching | Photoresist | Photoresist | Etching | Surface | |
|---|---|---|---|---|---|---|---|---|
| | Photoresist | solution | solution | stripper | Stripping Test | Precision | Resistance | Insulation |
| Embodiment 1 | A1 | B1 | C1 | D1 | ◯ | ◯ | ◯ | ◯ |
| Embodiment 2 | A1 | B2 | C1 | D1 | Δ | ◯ | ◯ | Δ |
| Embodiment 3 | A1 | B3 | C1 | D1 | ◯ | ◯ | ◯ | ◯ |
| Embodiment 4 | A1 | B1 | C2 | D1 | ◯ | ◯ | ◯ | Δ |
| Embodiment 5 | A1 | B1 | C3 | D1 | ◯ | ◯ | ◯ | Δ |
| Embodiment 6 | A1 | B1 | C4 | D1 | ◯ | ◯ | ◯ | Δ |
| Embodiment 7 | A1 | B1 | C5 | D1 | ◯ | ◯ | ◯ | Δ |
| Embodiment 8 | A1 | B1 | C1 | D2 | ◯ | ◯ | ◯ | ◯ |
| Embodiment 9 | A1 | B1 | C1 | D3 | ◯ | ◯ | ◯ | ◯ |
| Embodiment 10 | A2 | B1 | C1 | D1 | ◯ | ◯ | ◯ | ◯ |
| Comparative | a1 | b1 | C1 | d1 | ◯ | ◯ | X | ◯ |
| Embodiment 1 | | | | | | | | |
| Comparative | a2 | b2 | C1 | d2 | ◯ | ◯ | X | ◯ |
| Embodiment 2 | | | | | | | | |

The codes used to denote the reagents used in Table 1 are listed in the Tables A, B, C, and D below.

A. Photoresist

| Code | Model | type | Main component |
|---|---|---|---|
| A1 | HR-200 | negative | Cyclized polyisoprene |
| A2 | SC-100 | negative | Cyclized polyisoprene |
| a1 | TFP600 | positive | Novolak resin |
| a2 | AZ 6112 | positive | Naphthoquinone diazide derivative, |
| | | | and Novolak resin |

B. Developing Solution

| Code | Main component |
|---|---|
| B1 | Xylene |
| B2 | Phenylethane |
| B3 | Toluene |
| b1 | 2.38% TMAH |
| b2 | Potassium hydroxide |

C. Etching Solution

| Code | Main component | Concentration (wt %) |
|---|---|---|
| C1 | NaOCl | 12 |
| C2 | H₂O₂ | 35 |
| C3 | KMnO₄ | 5 |
| C4 | NaOH | 2.5 |
| C5 | KOH | 2.5 |

D. Photoresist Stripper

| Code | Main component | pH value |
|---|---|---|
| D1 | alkylbenzene sulfonic acid, and | Solvent type, not measureable |
| | heavy aromatic solvent naphtha | |
| | (EKC-922, from DuPont) | |
| D2 | 97 wt % H₂SO₄ | 0.3 |
| D3 | dodecyl benzenesulfonic acid | Solvent type, not measureable |
| d1 | N-methyl pyrrolidinone | 9 |
| | (AZ 400T, from AZ Electronic | |
| | Materials) | |
| d2 | N-methyl pyrrolidinone | 9 |
| | (AZ 300T, from AZ Electronic | |
| | Materials) | |

For embodiments 1 and 3, various developing solutions were used. Each developing solution could get excellent etching result without leaving residue photoresist, and the conductive line widths after etching were all more than 90 μm. The surface resistances were almost not changed by etching, and the surface resistances before and after etching were about 210Ω/□, i.e. R/Ro=1.00. The resistances of the etched areas were all more than 100 M·ohm. In Embodiment 2, phenylethane was used as the developing solution, and about 1-5% area was covered by residue photoresist. The resistance of the etched area was kind of lower, but still more than 78 M·ohm. Therefore, the resistance of the etched area was still within the acceptable ranges. For the etching precision and surface resistance tests of Embodiment 2, the results were all excellent.

In embodiments 1 and 4-7, various etching solutions were used. These etching solutions could gain good etching results. Comparing with Embodiment 1, the resistances of the etched area were a little bit lower for Embodiments 4-7 (25-100 M·ohm), but still within the acceptable range.

In embodiments 1 and 8-9, various photoresist strippers were used. These photoresist strippers could gain excellent etching result without leaving residue photoresist. The conductive line widths after etching were all more than 90 μm. The surface resistances were almost not changed by etching, and the surface resistances before and after etching were about 210Ω/□, i.e. R/Ro=1.00. The resistances of the etched areas were all more than 100 M·ohm.

In embodiment 1 and 10, various negative photoresists were used. Using these negative photoresist to perform photolithography and etching processes could gain excellent etching result without leaving residue photoresist. The conductive line widths after etching were all more than 90 μm. The surface resistances were almost not changed by etching, and the surface resistances before and after etching were about 210Ω/□, i.e. R/Ro=1.00. The resistances of the etched areas were all more than 100 M·ohm.

Contrarily, in comparison embodiments 1-2, various positive photoresists were used. Since the positive photoresists need alkaline photoresist stripper, the conductivity of the CNT conductive layer would be damaged by the alkaline photoresist stripper. Therefore, the surface resistance would be increased from 210Ω/□ to 680Ω/□, i.e. R/Ro=3.24.

In light of foregoing, the method provided by this disclosure can effectively etch the nonmetal conductive layer to obtain a highly-precision patterned nonmetal conductive layer without damaging the conductivity thereof. Therefore, this disclosure provides a method to significantly increase the convenience for processing nonmetal conductive layer. Accordingly, the performance of displays adopting the circuit boards having the nonmetal conductive layer patterned by the foregoing method can be effectively increased.

All the features disclosed in this specification (including any accompanying claims, abstract, and drawings) may be replaced by alternative features serving the same, equivalent or similar purpose, unless expressly stated otherwise. Thus, each feature disclosed is one example only of a generic series of equivalent or similar features.

What is claimed is:

1. A method of patterning a nonmetal conductive layer, comprising:
forming a nonmetal conductive layer on a substrate;
forming a negative photoresist layer on the nonmetal conductive layer, wherein a material of the negative photoresist layer is cyclized polyisoprene, an alkali-soluble acrylic resin, a copolymer containing hydroxystyrene monomer, or any combinations thereof;
exposing the negative photoresist layer through a patterned photomask by a radiation light;
developing the negative photoresist layer by a developing solution, which is xylene, phenylethane, toluene, or a combination thereof;
etching the nonmetal conductive layer by an etching solution; and
removing the exposed negative photoresist layer by a non-alkaline stripper or a solvent stripper.

2. The method of claim 1, wherein the substrate is made by a material of a polyester-based resin, a polyolefin-based resin, a polyvinyl-based resin, a cellulose ester, a polycarbonate-based resin, poly(vinyl acetate) and a derivative thereof, an acrylic resin, a polyamide, a polyimide, an am noplastic, a epoxide resin, a urethane, a polylsocyanurate, a furan resin, a silicone, a casesin resin, a cyclic thermoplastic, a fluorine-containing polymer, a polyethersulfone, or glass.

3. The method of claim 1, wherein the substrate is made from a polyester-based resin.

4. The method of claim 3, wherein the polyester-based resin is polyethylene terephthalate, or polyethylene naphthalate.

5. The method of claim 1, wherein the nonmetal conductive layer is made from a carbon nanomaterial, a conductive polymer, or a combination thereof.

6. The method of claim 5, wherein the carbon nanomaterial is carbon nanotube, carbon nanofiber, fullerene, graphene, or nano graphite.

7. The method of claim 6, wherein the carbon nanotube is single-walled carbon nanotube, double-walled carbon nanotube, multi-walled carbon nanotube, or any combinations thereof.

8. The method of claim 6, wherein a diameter and a length of the carbon nanotube is 1-50 nm and 1-20 μm, respectively.

9. The method of claim 5, wherein the conductive polymer is polypyrrole, polyaniline, polythiophene, or any combinations thereof.

10. The method of claim 9, wherein the conductive polymer is poly(3,4-ethylenedioxythiophene)-poly(styrenesulfonate).

11. The method of claim 1, wherein a main component of the negative photoresist layer is cyclized polyisoprene.

12. The method of claim 1, wherein the radiation light is UV light.

13. The method of claim 1, wherein the dose of the radiation light is at most 100 mJ/cm².

14. The method of claim 1, wherein the etching solution is sodium hypochlorite, hydrogen peroxide, potassium permanganate, potassium dichromate, sodium hydroxide, potassium hydroxide, or any combinations thereof.

15. The method of claim 1, wherein pH of the non-alkaline stripper is less than 7.

16. The method of claim 15, wherein a main component of the non-alkaline stripper is sulfuric acid.

17. The method of claim 1, wherein a main component of the solvent stripper is a mixture solution of alkylbenzene sulfonic acid and heavy aromatic solvent naphtha, or dodecyl benzenesulfonic acid.
